(19) United States
(12) Patent Application Publication
(10) Pub. No.: US 2006/0199330 A1
(43) Pub. Date: Sep. 7, 2006

(54) Method of manufacturing semiconductor memory having capacitor of high aspect ratio to prevent deterioration in insulating characteristics

(75) Inventors: Yoshitaka Nakamura, Tokyo (JP); Yoshihiro Takaishi, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMRY, INC., TOKYO (JP)

(21) Appl. No.: 11/363,996

(22) Filed: Mar. 1, 2006

(30) Foreign Application Priority Data
Mar. 1, 2005 (JP) 2005-055953

(51) Int. Cl. H01L 21/8242

(52) U.S. Cl. 438/253; 438/396

(57) ABSTRACT

A method of manufacturing a semiconductor memory according to the present invention includes steps of forming an insulating film, into which a conductive plug connected to a source or a drain in a transistor in a memory cell region and into which a first conductive layer which will become a part of a circuit in a peripheral circuit region are buried, on a semiconductor substrate, forming a first interlayer insulating film on the insulating film, forming, in the first interlayer insulating film, conductive plugs for connecting a first conductive layer and a second conductive layer arranged in a layer upper than the first interlayer insulating film, forming lower electrode of the capacitor in the first interlayer insulating film after the connection plugs are formed, forming capacitance insulating film, and forming upper electrode of the capacitor.

### BACKGROUND OF THE INVENTION

1. Field of the Invention

The present invention relates to a method of manufacturing a semiconductor memory.

2. Description of the Related Art

A memory cell such as DRAM (Dynamic Random Access Memory) includes a capacitor and a transistor to select the capacitor. Hereinafter this transistor is referred to as a “selection transistor”. Finer memory cells with the advance in fine patterning technology cause a problem in that the amount of charge storage is reduced in the capacitor. To solve this problem, the COB (Capacitor Over Bitline) structure and the STC (Stacked Trench Capacitor) structure have been introduced. In other words, the capacitor is formed on the bit line to allow the bottom area (projected area) of the capacitor to be larger. Also, by allowing the height of the capacitor to be larger, the area of the capacitor electrode is increased.

A representative example of the memory cell is disclosed in Japanese Patent Laid-open No. 11-243180 (hereinafter, called Patent Document 1). FIGS. 2 and 3 in Patent Document 1 show the configuration thereof, and pages 7 to 9 describe explanations of the configuration. According to the disclosed example, in the peripheral circuit region, a connection plug of a silicon diffusion layer and a lower layer of a capacitor is formed prior to the formation of capacitor so as to prevent deterioration in the capacitor resulting from heat treatment for forming the connection plug.

However, with the advance of being finer, the height of the capacitor increases, while the height of the connection for connecting wiring layers under and over the capacitor increases. As another problem, how to form a connection plug having a high aspect ratio is raised. This situation will be explained in detail.

First, the conventional method of forming the connection plug is explained. After making a contact hole, a titanium nitride (TiN) film is formed on a side wall and in the bottom of the contact hole as a basic film by the sputtering method. Then, a tungsten (W) film is buried in the contact hole by the CVD (Chemical Vapor Deposition) method. Further, with the CMP (Chemical and Mechanical Polishing) method or the like, the titanium nitride film and the tungsten film are polished to form a plug. In forming a connection plug having a high aspect ratio like this, when the titanium nitride film is formed by the sputtering method, the titanium nitride film does not function as the basic film, and thus it causes a problem such as poor coverage in the tungsten film.

To solve this problem, in recent years, a method has been adopted in which the titanium nitride film is formed by the CVD method. This method produces a certain effect of preventing the tungsten film from poor coverage.

However, the formation temperature of the titanium nitride film as the basic film of the connection plug is generally set at 550° C. or more, typically, about 600° C. Therefore, when the CVD formation technique of the titanium nitride film is applied to plug 38 connecting conductive layers over and under the capacitor in the disclosed example in Patent Document 1 as it is, the characteristics of the capacitor deteriorate caused by the thermal load of the CVD.

This situation is explained in detail. FIG. 1 is a longitudinal sectional view showing a conventional representative example of a semiconductor memory. In the memory cell region in FIG. 1, two selection transistors are formed in an active region which the main surface of silicon substrate 10 is partitioned by isolation insulating film 2. Each selection transistor includes gate electrode 4 disposed over the main surface of silicon substrate 10 with gate insulating film 3 and a pair of diffusion layer regions 5, 6 to be a source region and a drain region, and diffusion layer regions 6 of the respective selection transistors are integrated and shared.

In the selection transistor, bit line 8 (made of tungsten film) formed on interlayer insulating film 21 and interlayer insulating film 31 and one diffusion layer region 6 are connected by polysilicon plug 11a that penetrates interlayer insulating film 21. Since conductive impurities are diffused in polysilicon plug 11a, polysilicon plug 11a functions as a conductive plug. The following similarly applies to the polysilicon plug.

Bit line 8 is covered by interlayer insulating film 22. The capacitor is formed in a hole arranged in interlayer insulating film 32 and interlayer insulating film 23 formed on interlayer insulating film 22 so that lower electrode 51 made of a first titanium nitride film, a capacitance insulating film made of aluminum oxide film 52, and an upper electrode made of a second titanium nitride film are successively disposed. The bottom of lower electrode 51 is connected with polysilicon plug 12. Further, polysilicon plug 12 is electrically connected to diffusion layer region 5 in the transistor through polysilicon plug 11 under polysilicon plug 12.

Also, on second titanium nitride film 53 which will become the upper electrode, second layer wiring 61 is formed. Second titanium nitride film 53 and second layer wiring 61 are electrically connected by connection plug 44 formed by penetrating interlayer insulating film 24. On the other hand, in the peripheral circuit region, a transistor for a peripheral circuit is formed in the active region in which the main surface of silicon substrate 10 is partitioned by isolation insulating film 2. The transistor for the peripheral circuit includes gate electrode 4 formed on gate insulating film 3 and a pair of diffusion layer regions 7, 7a which will become a source region and a drain region. One diffusion layer region 7 in the transistor is electrically connected with second layer wiring 61 through metal plugs 41, 43, and the other diffusion layer region 7a is electrically connected to first layer wiring 8a through metal plug 41a. Further, first layer wiring 8a is electrically connected to second layer wiring 61a through metal plug 42.

Next, the conventional example of the method of manufacturing the semiconductor memory is explained with reference to FIG. 2 to FIG. 12.

The main surface of silicon substrate 10 is partitioned by isolation insulating film 2. Gate oxide film 3, gate electrode 4, diffusion layer regions 5, 6, 7, 7a, polysilicon plugs 11, 11a, metal plugs 41, 41a, bit line 8, and first layer wiring 8a are formed (FIG. 2). In this example, bit line 8 and first layer wiring 8a are made of tungsten film, however, they may be made of a laminated film including a tungsten film. The contact hole penetrating interlayer insulating film 22 formed on bit line 8 and first layer wiring 8a is buried with a polysilicon film, and then is etched back to form polysilicon plug 12 (FIG. 3). Successively, a silicon nitride film is formed as interlayer insulating film 32, and then a silicon nitride film of 3 um in thickness is formed as interlayer insulating film 23 (FIG. 4). Further, cylinder hole 96 that penetrates interlayer insulating films 23, 32 is formed, and the surface of polysilicon plug 12 is exposed to the bottom of cylinder hole 96 (FIG. 5).

Then, titanium nitride film 51a is formed as the lower electrode by the CVD method (FIG. 6). Successively, a photoresist film is formed above the hole. While the titanium nitride film in the hole is protected, the titanium nitride film above the hole is etched-back and removed, and the photoresist film is removed so as to obtain lower electrode 51 in a cup shape (FIG. 7). Then, aluminum oxide film 52 is formed by the ALD (Atomic Layer Deposition) method, and second titanium nitride film 53 is formed as the upper electrode by the CVD method at the film formation temperature of 500° C. (FIG. 8). Second titanium nitride film 53 is processed into the shape of an upper electrode by the photolithography technique and the dry etching technique (FIG. 9), and a capacitor in a cylindrical shape of 3 um in height is obtained. Successively, interlayer insulating film 24 made of the silicon oxide film is formed (FIG. 10), and then interlayer insulating film 24 is penetrated so as to make connection hole 94, and interlayer insulating films 24, 23, 32, 22 are penetrated so as to make connection holes 93, 92 (FIG. 11).

Successively, the third titanium nitride film and the tungsten film are buried in connection holes 92, 93, 94, and then the third titanium nitride film and the tungsten film are removed except from the connection holes by the CMP method so as to form metal plugs 42, 43, 44 (FIG. 12). In this example, the third titanium nitride film is formed by using titanium tetrachloride (TiCl₄) and ammonia (NH₃) as raw-material gas by the CVD method at the film formation temperature of 600° C.

The reasons for performing this at the film formation temperature of 600° C. are explained next. If the temperature is below 600° C., two problems will occur. One of two problems is that the stress of the titanium nitride film will increase to cause delamination. The other of two problems is that the amount of residual chlorine in the titanium nitride film will increase to cause second layer wirings 61, 61a to corrode.

Then, a titanium film, an aluminum film, and a titanium nitride film are formed sequentially by the sputtering method. Successively, the laminated film is patterned by the photolithography technique and the dry etching technique so as to form second layer wirings 61, 61a (FIG. 1).

FIGS. 13A and 13B are graphs showing I-V characteristics of the capacitor obtained according to the example shown in the conventional method of manufacturing. Formation condition and measurement condition for this capacitor are shown.

Formation Condition

Cylinder Hole: cylinder of 210 nm in diameter and 3 um in depth

Lower Electrode: titanium nitride film that is 20 nm in thickness (film formation temperature: 600° C., CVD method)

Aluminum Oxide Film: thickness of 6 nm (film formation temperature: 400° C., ALD method)

Upper Electrode: titanium nitride film of 20 nm in thickness (film formation temperature: 500° C., CVD method)

Measurement Condition

Measurement TEG: memory cell array of 274 kbit

Temperature: 90° C.

Vertical axes in the graphs shown in FIGS. 13A and 13B represent values of leakage currents flowing only in the capacitor of the measurement TEG, and horizontal axes represent voltage values applied between the upper electrode and the lower electrode. FIG. 13A shows a case where a positive voltage is applied, and FIG. 13B shows a case where a negative voltage is applied.

Broken lines shown in the graphs in FIGS. 13A and 13B represent characteristics that were measured immediately after formation of the capacitor, namely, in the state shown in FIG. 9. On the other hand, solid lines shown in the graphs in FIGS. 13A and 13B represent characteristics that were measured immediately after formation of the second layer wiring, namely, in the state shown in FIG. 1. The leakage current in the characteristics represented by the solid lines is ten times larger than that in the characteristics represented by the broken lines. As the result of the analysis, it is understood that the leakage current in the characteristics represented by the solid lines is caused by the CVD process for the titanium nitride film when metal plugs 41, 42, 43 are formed. As described above, since a capacitor is an element with low resistance to thermal loads, it is necessary to set the process temperature as low as possible after formation of the capacitor.

### SUMMARY OF THE INVENTION

Accordingly, it is an object of the present invention to provide a method of manufacturing a semiconductor memory having a capacitor of a high aspect ratio to prevent deterioration in capacitor characteristics.

A method of manufacturing a semiconductor memory according to the present invention is a method that includes a plurality of capacitors holding information and transistors respectively provided for said capacitors and a peripheral circuit region provided with a circuit electrically connected to the memory cell region, and the method includes steps of forming an insulating film, into which a conductive plug connected to a source or a drain in a transistor in a memory cell region and into which a first conductive layer which will become a part of a circuit in a peripheral circuit region are buried, on a semiconductor substrate, then the steps of forming a first interlayer insulating film on the insulating film, forming, in the first interlayer insulating film, conductive plugs for connecting a first conductive layer and a second conductive layer arranged in an layer upper than the first interlayer insulating film, forming lower electrode of the capacitor in the first interlayer insulating film after the connection plugs are formed, forming capacitance insulating film, and forming upper electrode of the capacitor.

According to the present invention, after formation of connection plugs, a lower electrode, a capacitance insulating film, and an upper electrode for a capacitor are formed. Therefore, the thermal load on the capacitor is reduced. As a result, it is possible to prevent leakage currents in the capacitor from increasing and to prevent the capacitor characteristics from deteriorating. Accordingly, the reliability of the capacitor is improved. Additionally, when conductive materials for a contact plug having a high aspect ratio for connecting conductive layers formed under and over the capacitor are formed by the CVD method, there is no problem of poor coverage in the contact plug, and the reliability of wirings is improved. By applying the present invention to a semiconductor memory such as DRAM, the reliability of the semiconductor memory is improved.

The above and other objects, features and advantages of the present invention will become apparent from the following description with reference to the accompanying drawings which illustrate examples of the present invention.

### BRIEF DESCRIPTION OF THE DRAWINGS

FIG. 1 is a longitudinal sectional view showing a configuration example of a conventional semiconductor memory;

FIG. 2 to FIG. 12 are longitudinal sectional views showing respective steps in the method of manufacturing the conventional semiconductor memory;

FIGS. 13A and 13B are graphs showing I-V characteristics of a capacitor in conventional semiconductor memory;

FIG. 14 is a longitudinal sectional view showing a configuration example of a semiconductor memory according to a first embodiment;

FIG. 15 to FIG. 25 are longitudinal sectional views showing respective steps in the method of manufacturing the semiconductor memory according to the first embodiment;

FIG. 26 to FIG. 35 are longitudinal sectional views showing respective steps in a method of manufacturing the semiconductor memory according to a second embodiment; and

FIG. 36 to FIG. 45 are longitudinal sectional views showing respective steps in a method of manufacturing the semiconductor memory according to a third embodiment.

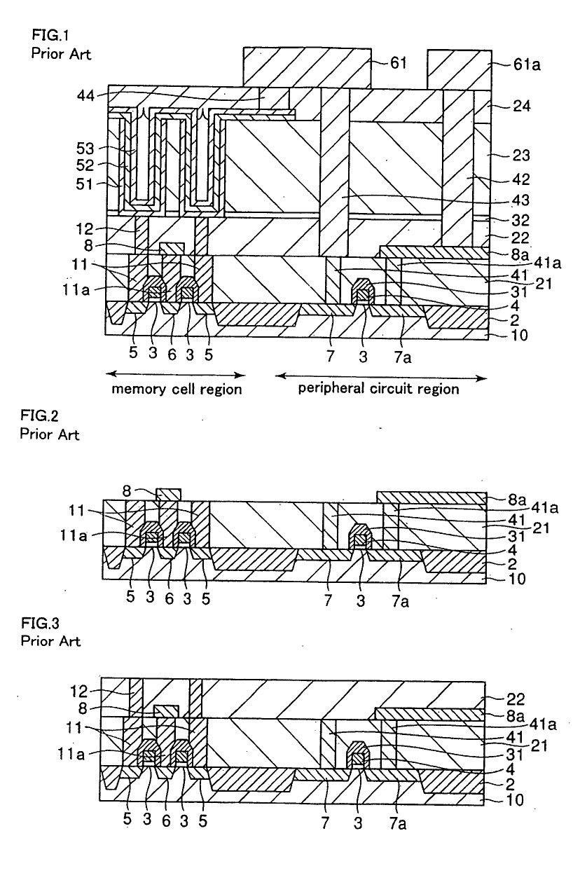

### DETAILED DESCRIPTION OF THE PREFERRED EMBODIMENTS

The method of manufacturing the semiconductor memory according to the present invention is characterized in that, before a capacitor having a high aspect ratio is formed, connection plugs for connecting conductive layers arranged in upper and lower layers of the capacitor are formed.

### First Embodiment

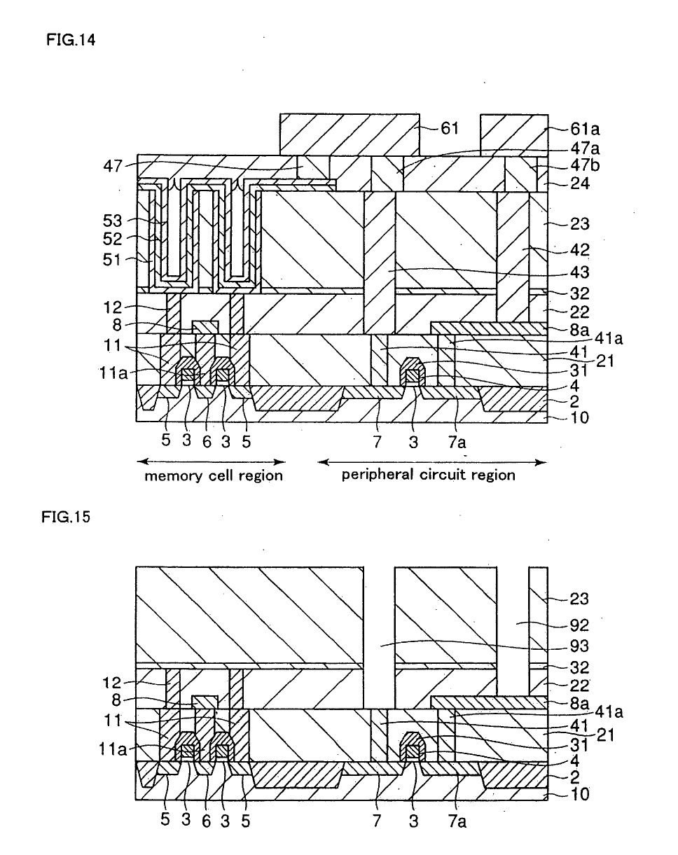

Explanations will be given of the configuration of semiconductor memory according to the first embodiment of the present invention. FIG. 14 is a sectional view showing a configuration example of a semiconductor memory according to the first embodiment.

As shown in FIG. 14, the semiconductor memory of the first embodiment is provided with a peripheral circuit region where connection plugs 42, 43 are connected to second layer wirings 61, 61a through connection plugs 47a, 47b.

Next, the method of manufacturing the semiconductor memory according to the first embodiment of the present invention will be explained with reference to FIG. 15 to FIG. 25.

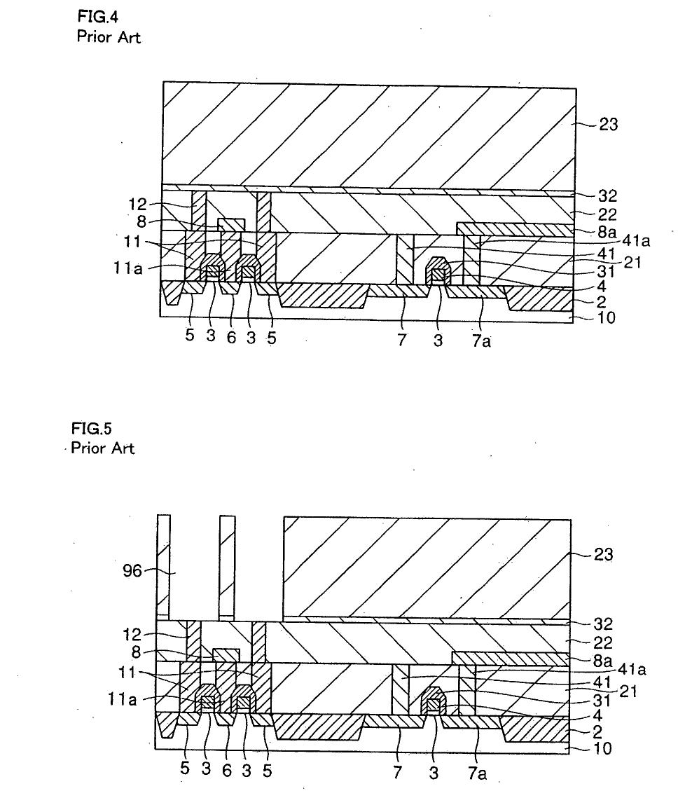

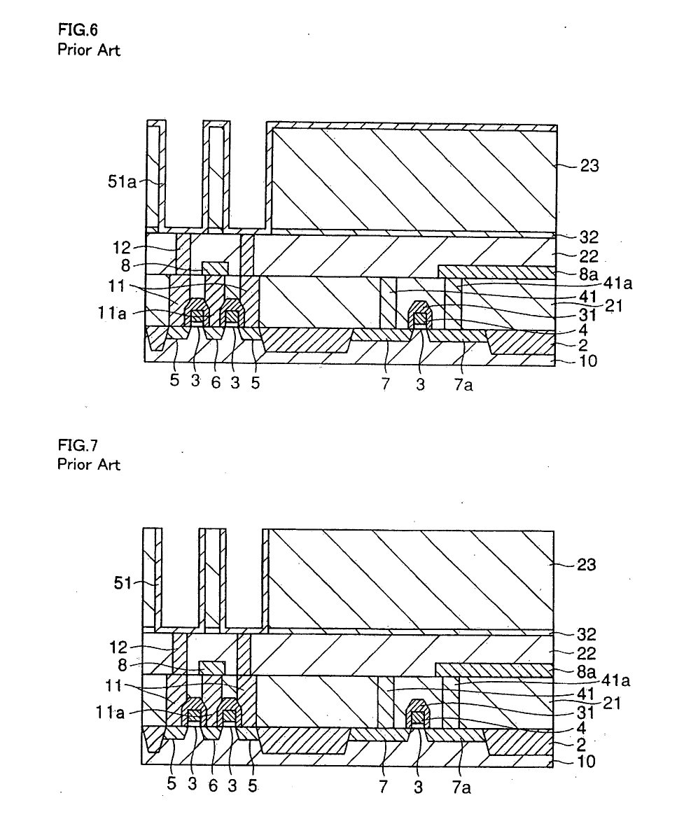

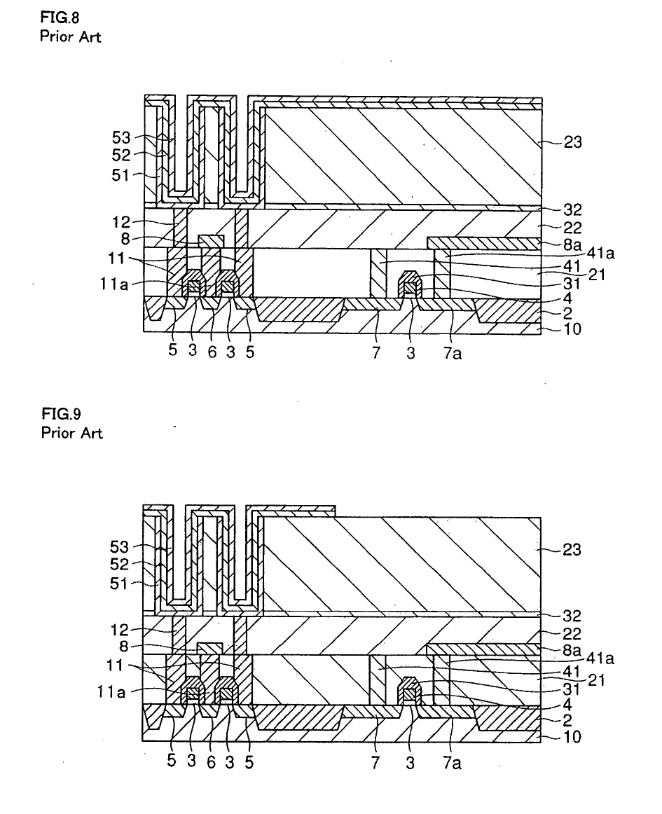

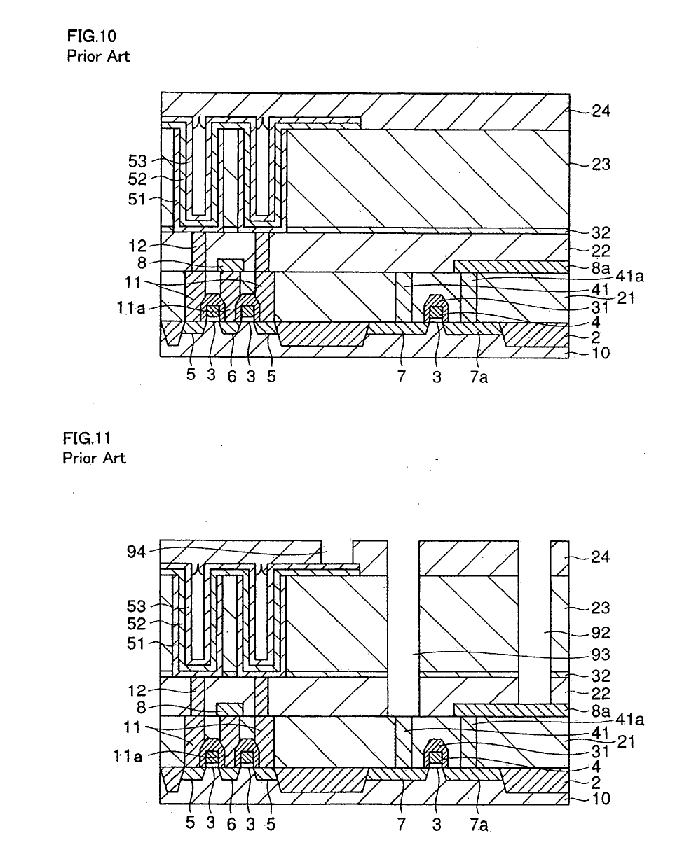

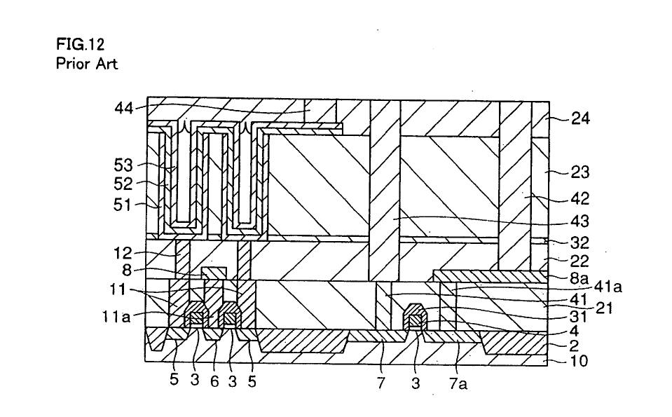

First, similar to the conventional example, isolation insulating film 2, gate oxide film 3, gate electrode 4, diffusion layer regions 5, 6, 7, 7a, polysilicon plugs 11, 11a, metal plugs 41, 41a, bit line 8, first layer wiring 8a, interlayer insulating films 31, 22, polysilicon plug 12, and interlayer insulating films 32, 23 are formed sequentially (refer to FIG. 4).

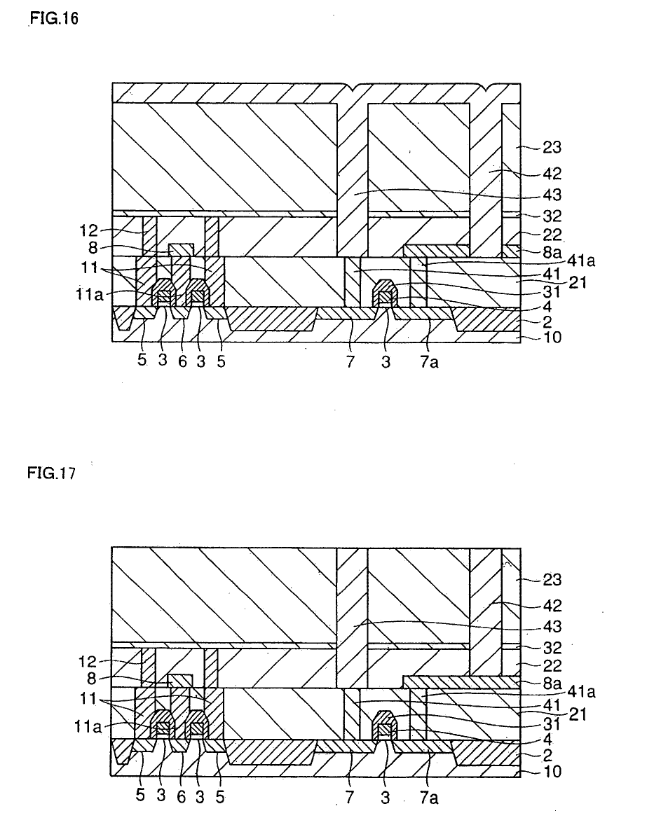

Successively, interlayer insulating films 23, 32, 22 are penetrated so as to make connection holes 92, 93 (FIG. 15). Then, the third titanium nitride film and the tungsten film are buried in connection holes 92, 93 (FIG. 16). In this embodiment, the third titanium nitride film is formed by using titanium tetrachloride and ammonia as raw-material gas by the CVD method at the film formation temperature of 600° C., and then the tungsten film is formed by the CVD method at the film formation temperature of 400° C. After that, the third titanium nitride film and the tungsten film are removed except from the connection holes by the CMP method, and metal plugs 42, 43 are formed (FIG. 17).

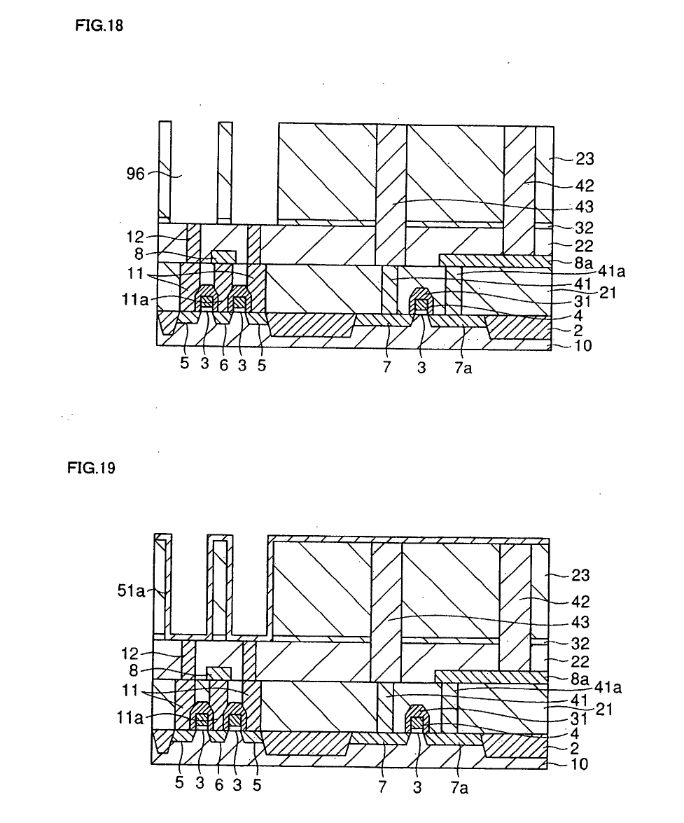

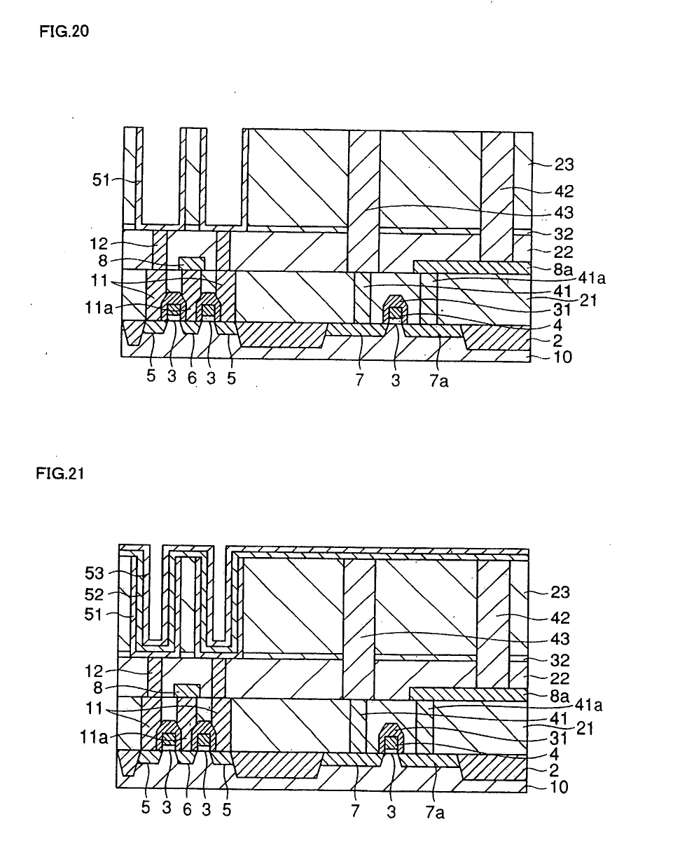

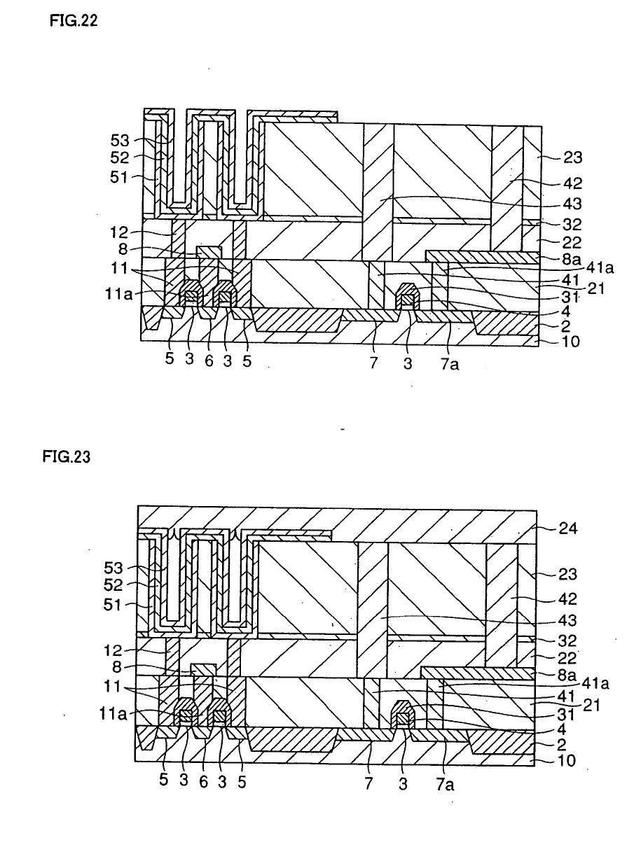

Successively, cylinder hole 96 penetrating these interlayer insulating films 23, 32 is formed, and the surface of polysilicon plug 12 is exposed to the bottom of cylinder hole 96 (FIG. 18). Then, titanium nitride film 51a is formed as the lower electrode by the CVD method (FIG. 19), and, similar to the conventional example, the titanium nitride film above the hole is etched-back and removed so as to obtain lower electrode 51 in a cup shape (FIG. 20). Then, similar to the conventional example, aluminum oxide film 52 and second titanium nitride film 53 are formed (FIG. 21). Second titanium nitride film 53 is processed into the shape of an upper electrode (FIG. 22) and interlayer insulating film 24 is formed (FIG. 23).

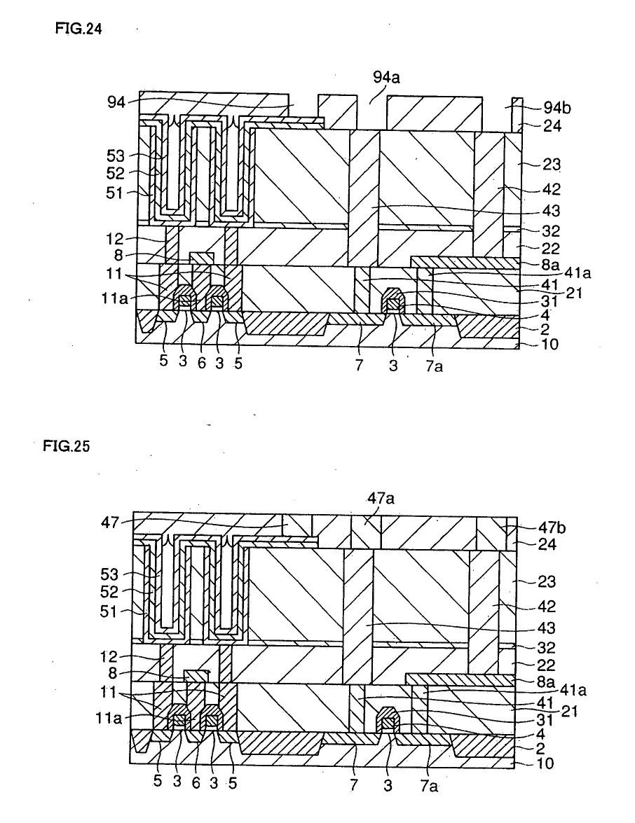

Then, interlayer insulating film 24 is penetrated so as to make connection holes 94, 94a, 94b (FIG. 24). Successively, a fourth titanium nitride film and the tungsten film are buried in connection holes 94, 94a, 94b, and then the fourth titanium nitride film and the tungsten film are removed except from the connection holes by the CMP method so as to form metal plugs 47, 47a, 47b (FIG. 25). In this embodiment, the fourth titanium nitride film is formed by the sputtering method at the film formation temperature of 400° C. However, since the depths of holes are shallow (about 200 nm), there is no problem of poor coverage or the like about the fourth titanium nitride film. Then, a titanium film, an aluminum film, and a titanium nitride film are formed sequentially by the sputtering method, and the laminated film thereof is patterned so as to form second layer wirings 61, 61a (FIG. 14).

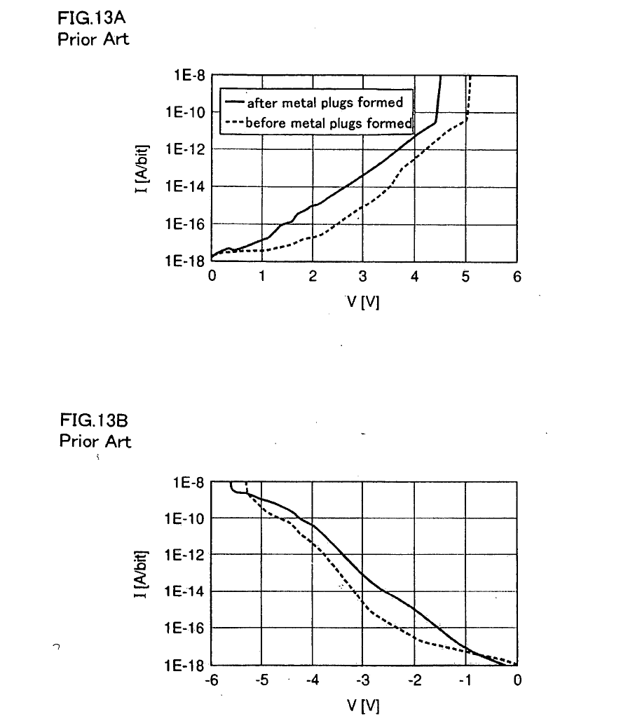

According to the method of manufacturing the semiconductor memory according to this embodiment, the I-V characteristics that were measured after second layer wirings 61, 61a are formed (FIG. 14) are similar to the I-V characteristics indicated by the broken lines shown in the graphs in FIGS. 13A and 13B, namely, the I-V characteristics that were measured immediately after formation of the capacitor. At the time after second layer wirings 61, 61a are formed, the insulating characteristics are superior to those in the conventional example. As described above, the process of forming titanium nitride, which requires a high temperature process, and which is based on the CVD method, is performed prior to the process for forming the capacitor, and thus it is possible to prevent leakage currents in the capacitor from increasing and to prevent the characteristics of the capacitor from deteriorating.

When the bit line is formed in a layer lower than the capacitor, as in this embodiment, metal plugs 42, 43 for connecting the conductive layer formed above the capacitor and the conductive layer formed in a layer lower than the capacitor are formed in the holes having high aspects ratios. According to this embodiment, even if the height of the capacitor is 3 um or more, at the time of forming metal plugs 42, 43, the third titanium nitride film formed on the side walls and the bottoms of the holes is formed by the CVD method. Therefore, there is no problem of poor coverage. Incidentally, metal plugs 42, 43 are made of the laminated film of the titanium nitride film and the tungsten film, however, they may be formed by a single layer film of titanium nitride film. Also, the film formation temperature of the third titanium nitride film may be 550° C. or more, however, preferably 600° C. or more.

Also, since the capacitor is formed after metal plugs 42, 43 are formed, the formation temperature of the third titanium nitride film can be set higher than the formation temperature and the crystallization temperature of the capacitance insulating film. When heat treatments are at a temperature higher than the crystallization temperature, after the capacitance insulating film is formed, crystallization is promoted and leakage currents in the capacitor are increased.

Additionally, in this embodiment, the example is described in which metal plugs 47, 47a, 47b are formed by employing titanium nitride film and tungsten film that are formed by the sputtering method separately from second layer wirings, however, the titanium nitride film and the aluminum film may be formed by the sputtering method and the reflow technique may be applied so as to form metal plugs and second layer wirings simultaneously. Further, the groove wiring formation technique (so-called damascene technique) of a tantalum nitride film and a copper film is also available.

Also, this embodiment shows the example for applying this invention to a semiconductor memory having a capacitor of the MIM (Metal Insulator Metal) type which uses the titanium nitride film as the lower electrode, however, the present invention may be applied to a semiconductor memory having a capacitor of a MIS (Metal Insulator Semiconductor) type which uses a polysilicon film.

Further, the first embodiment shows the example in which the aluminum oxide film is used as the capacitance insulating film, however, instead of the aluminum oxide film, a hafnium oxide film, a tantalum oxide film, and a zirconium oxide film may be used or a laminated film thereof may be used. In particular, when the hafnium oxide film is used, leakages currents are substantially increased which is caused by crystallization promoted by heat treatment over 500° C., however, by applying the present invention, the leakages currents can be substantially reduced.

### Second Embodiment

A difference between the second embodiment and the first embodiment is that one interlayer insulating film is added after metal plugs 42, 43 are formed to prevent the film of the lower electrode and the metal plugs from coming into contact and reacting. In this embodiment, even if a polysilicon film is used as the lower electrode and a metal plug includes a tungsten film, it is possible to avoid problems in which, because of the reaction of both and the formation of tungsten silicide, the resistance values of the metal plugs are raised and abnormal growth occurs during formation of polysilicon.

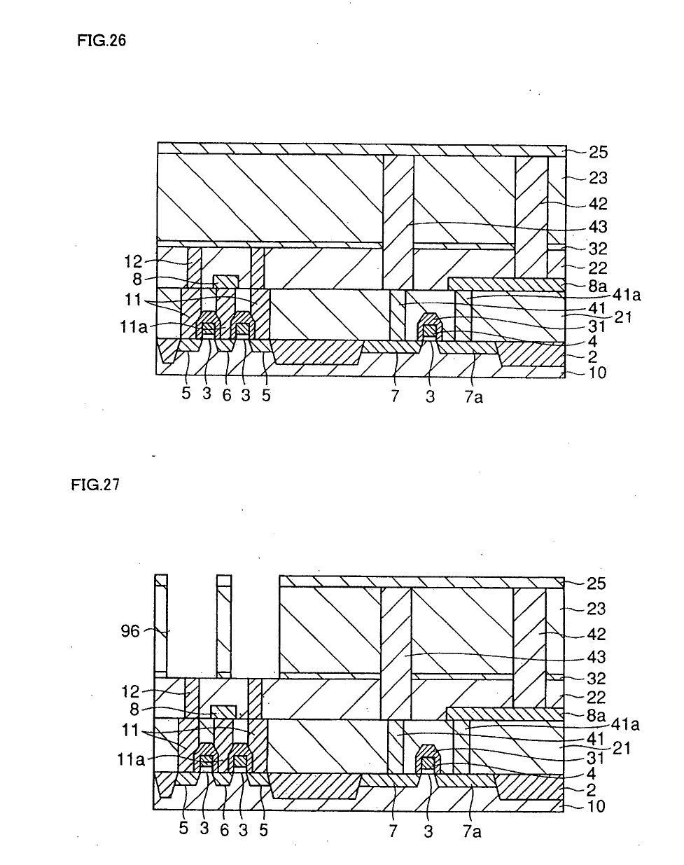

Next, the method of manufacturing a semiconductor memory having a capacitor of the MIM type according to the second embodiment of the present invention will be explained with reference to FIG. 26 to FIG. 35.

First, similar to the first embodiment, isolation insulating film 2, gate oxide film 3, gate electrode 4, diffusion layer regions 5, 6, 7, 7a, polysilicon plugs 11, 11a, metal plugs 41, 41a, bit line 8, first layer wiring 8a, interlayer insulating films 31, 22, polysilicon plug 12, interlayer insulating films 32, 23, and metal plugs 42, 43 are formed sequentially (refer to FIG. 17). Then, a silicon oxide that is 100 nm in thickness is formed as interlayer insulating film 25 (FIG. 26). Successively, cylinder hole 96 penetrating interlayer insulating films 25, 23, 32 is formed, and the surface of polysilicon plug 12 is exposed to the bottom of cylinder hole 96 (FIG. 27).

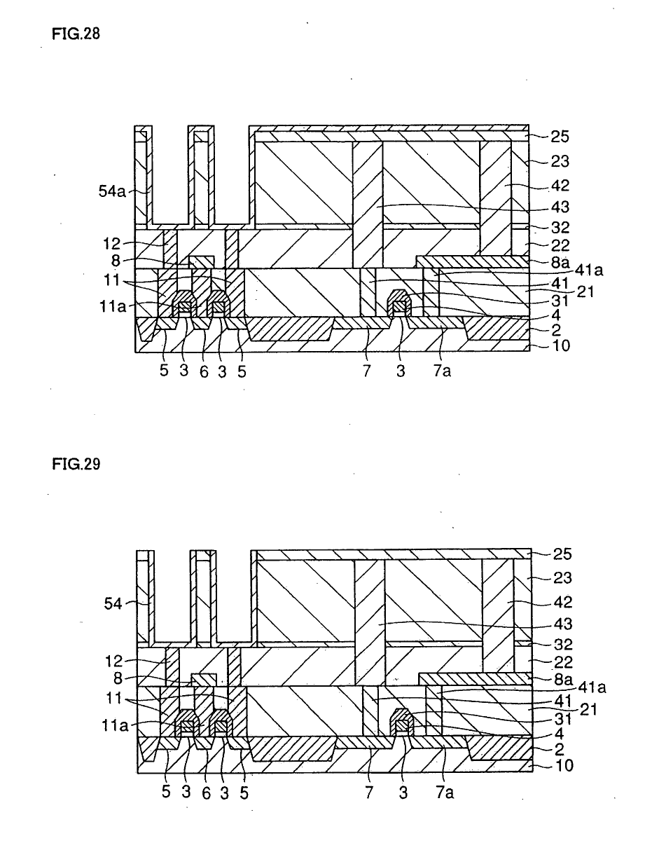

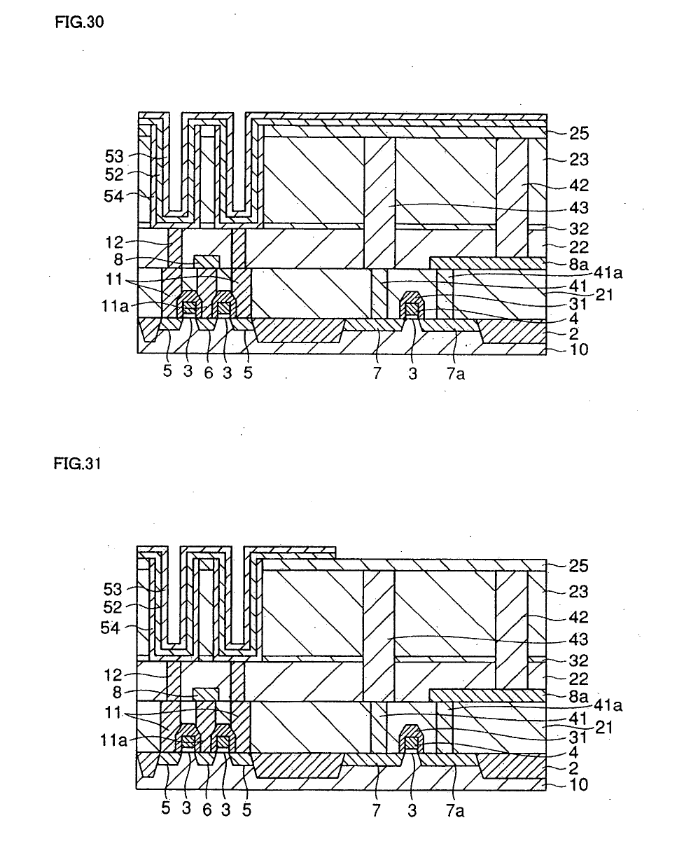

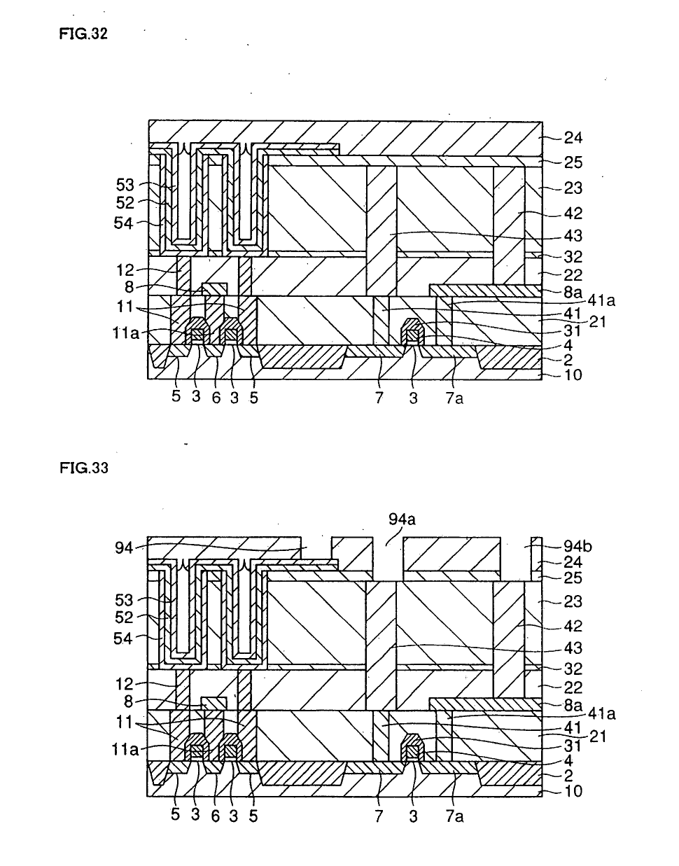

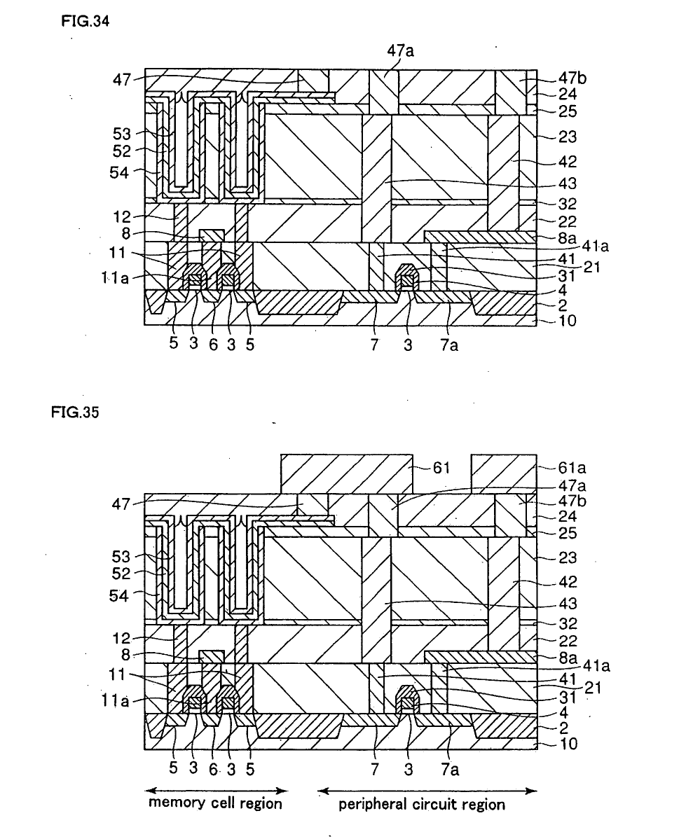

Then, titanium nitride film 54a is formed as the lower electrode by the CVD method (FIG. 28), and, similar to the conventional example, the titanium nitride film above the hole is etched-back and removed so as to obtain lower electrode 51 in a cup shape (FIG. 29). Then, similar to the conventional example, aluminum oxide film 52 and second titanium nitride film 53 are formed (FIG. 30). Second titanium nitride film 53 is processed into the shape of the upper electrode (FIG. 31) and interlayer insulating film 24 is formed (FIG. 32). Then, similar to the first embodiment, connection holes 94, 94a, 94b are made (FIG. 34), metal plugs 47, 47a, 47b are formed (FIG. 34), and second layer wirings 61, 61a are formed (FIG. 35).

According to this embodiment, in the production process, tungsten in metal plugs 47, 47a, 47b and polysilicon film 54a in the lower electrode are separated by interlayer insulating film 25 so as not to be contact directly. Therefore, tungsten silicide is not formed and abnormal formation does not occur during the growth of polysilicon. Incidentally, the production process described in the first embodiment may be applied to the second embodiment.

### Third Embodiment

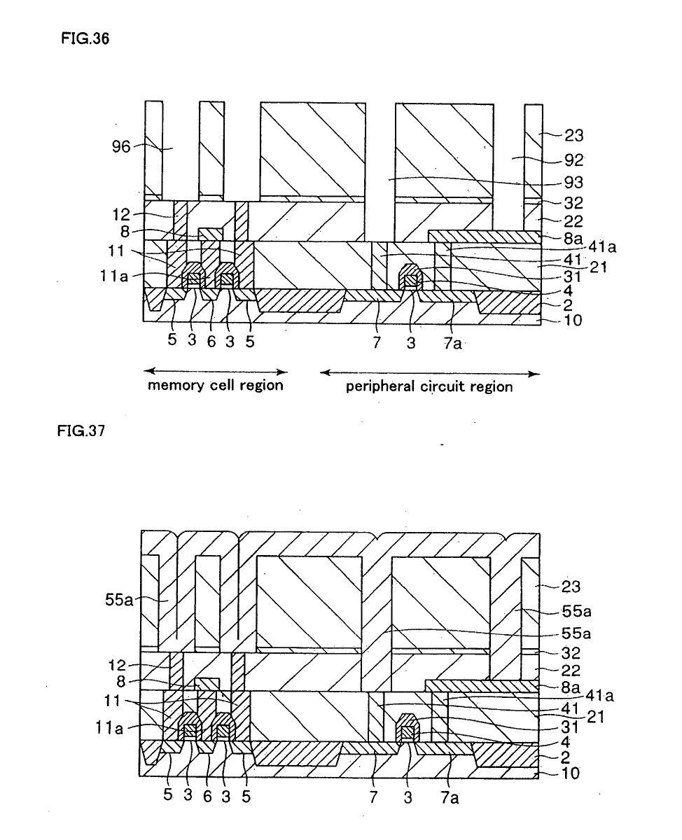

The third embodiment shows the example for applying this invention to a capacitor having a lower electrode of a pedestal (pillar) structure. The method of manufacturing the semiconductor memory according to the third embodiment of the present invention will be explained with reference to FIG. 36 to FIG. 45.

First, similar to the conventional example, isolation insulating film 2, gate oxide film 3, gate electrode 4, diffusion layer regions 5, 6, 7, 7a, polysilicon plugs 11, 11a, metal plugs 41, 41a, bit line 8, first layer wiring 8a, interlayer insulating film, 22, polysilicon plug 12, and interlayer insulating films 32, 23 are formed sequentially (refer to FIG. 4). Successively, cylinder hole 96 that penetrates interlayer insulating films 23, 32 is formed, and the surface of polysilicon plug 12 is exposed to the bottom of cylinder hole 96. On the other hand, connection holes 92, 93 that penetrates interlayer insulating films 23, 32, 22 are formed, and the surfaces of first layer wiring 8a and metal plug 41 are exposed to the bottoms of connection holes 92, 93 (FIG. 36).

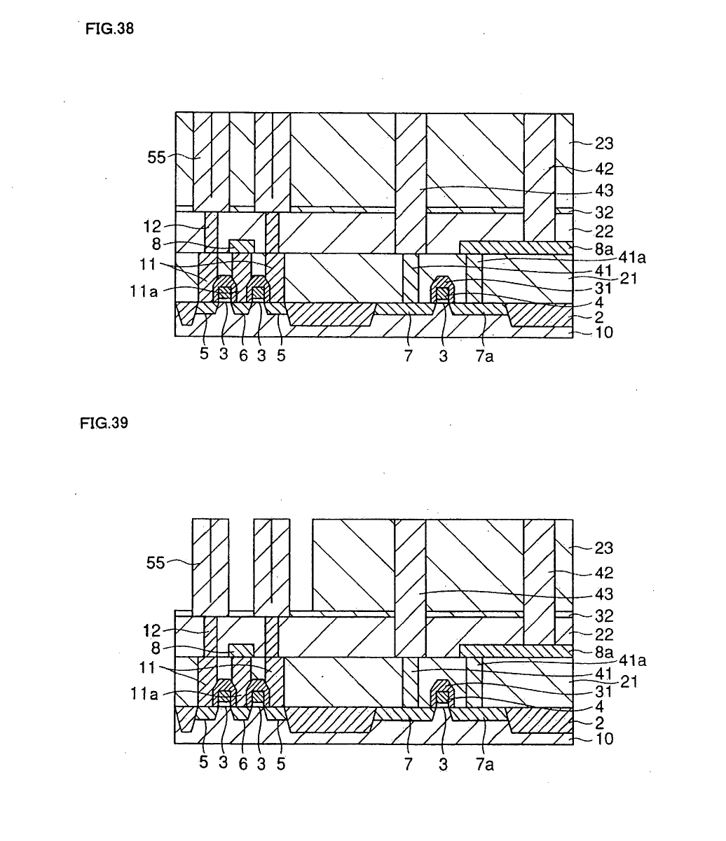

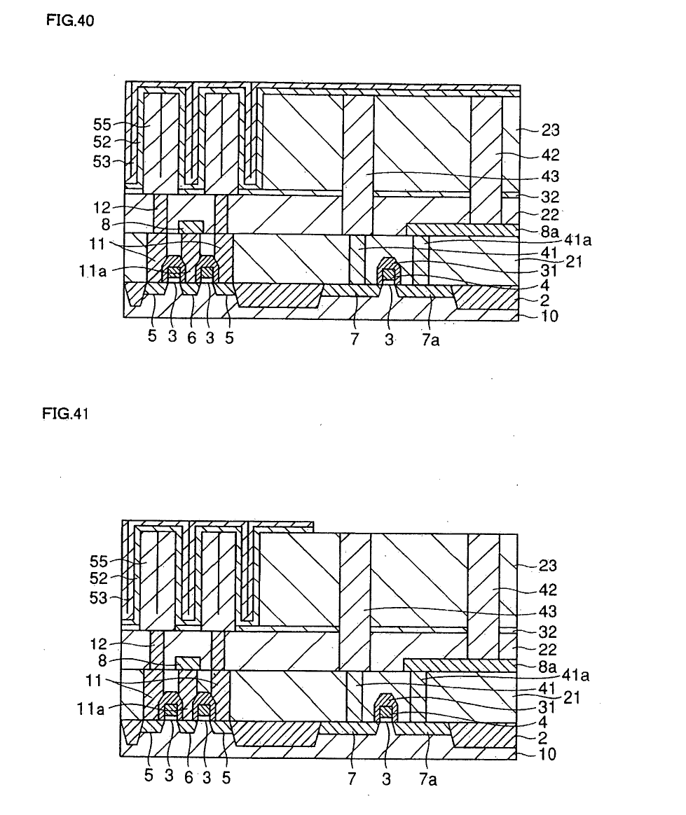

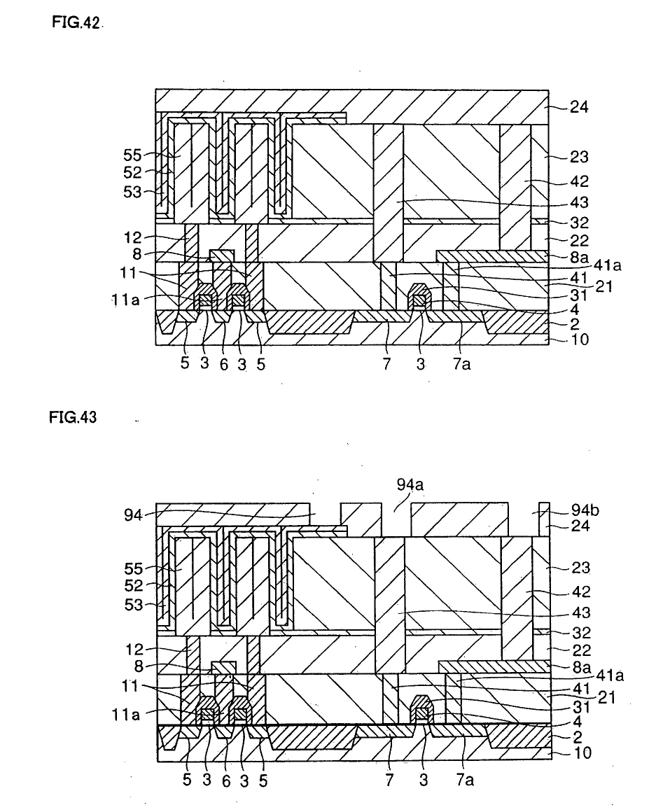

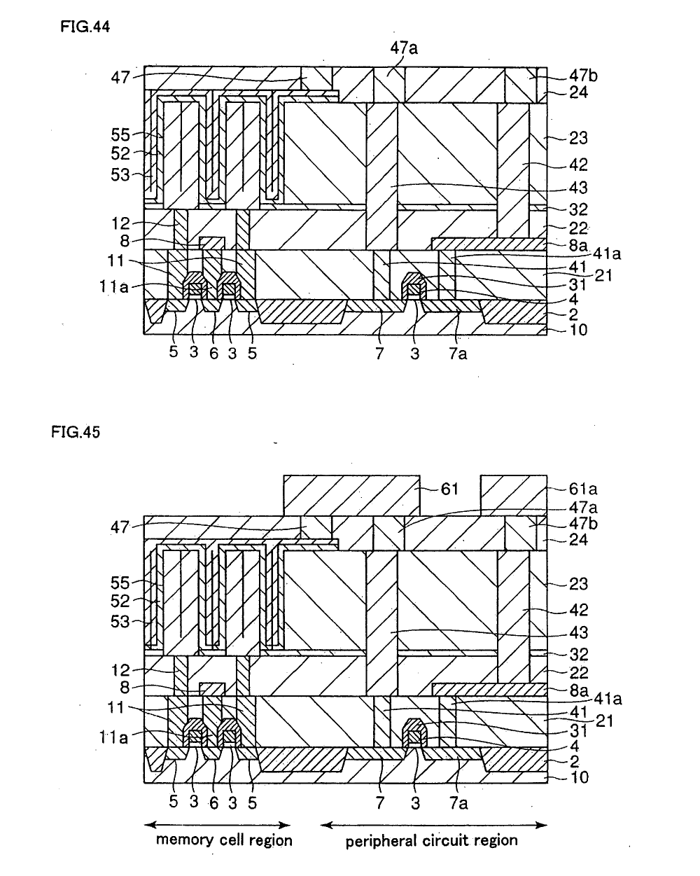

Then, first titanium nitride film 55a is formed by the CVD method, and is buried in cylinder hole 96 and connection holes 92, 93 (FIG. 37). Then, the titanium nitride film is removed except from cylinder hole 96 and connection holes 92, 93 by the CMP method (FIG. 38). Successively, interlayer insulating film 23 in the memory cell region is removed by the photolithography technique and the dry etching technique as usual (FIG. 39). Then, similar to the conventional example, aluminum oxide film 52 and second titanium nitride film 53 are formed (FIG. 40). Second titanium nitride film 53 is processed into the shape of the upper electrode (FIG. 41) and interlayer insulating film 24 is formed (FIG. 42). Then, similar to the first embodiment, connection holes 94, 94a, 94b are made (FIG. 43), metal plugs 47, 47a, 47b are formed (FIG. 44), and second layer wirings 61, 61a are formed (FIG. 45).

As described in this embodiment, the present invention may be applied to a capacitor having a lower electrode of the pedestal (pillar) structure. Also, as described in this embodiment, lower electrode 55 and the titanium nitride film of metal plugs 42, 43 are formed at the same time so that the number of steps can be reduced. Needless to say, lower electrode 55 and metal plugs 42, 43 may be formed separately and may be made from other materials.

Additionally, the use of the present invention is not limited to DRAM, and a combined LSI including DRAM may be used.

While preferred embodiments of the present invention have been described using specific terms, such description is for illustrative purposes only, and it is to be understood that changes and variations may be made without departing from the spirit or scope of the following claims.

What is claimed is:

1. A method of manufacturing a semiconductor memory having a memory cell region including a plurality of capacitors holding information and transistors respectively provided for said capacitors and a peripheral circuit region provided with a circuit electrically connected to the memory cell region, comprising the steps of:
forming an insulating film, into which a conductive plug connected to a source or a drain in said transistor and into which a first conductive layer which will become a part of said circuit are buried, on a semiconductor substrate;
forming a first interlayer insulating film on said insulating film;
forming, in said first interlayer insulating film, a connection plug for connecting said first conductive layer and a second conductive layer arranged in an layer upper than said first interlayer insulating film;
forming a lower electrode of said capacitor, for connecting with said conductive plug, after the connection plug is formed;
forming a capacitance insulating film in contact with said lower electrode; and
forming an upper electrode of said capacitor in contact with said capacitance insulating film.

2. The method according to claim 1, wherein a bit line being connected to said source or said drain which ever is open in said transistor is arranged in said insulating film.

3. The method according to claim 1, wherein a height of said capacitor is 3 um or more.

4. The method according to claim 1, wherein said first conductive layer is a tungsten film or a laminated film that includes the tungsten film.

5. The method according to claim 2, wherein said first conductive layer is arranged in the same layer as said bit line.

6. The method according to claim 1, wherein said second conductive layer is a laminated film that includes an aluminum film.

7. The method according to claim 1, wherein said connection plug is made of a titanium nitride film formed by a CVD method or a film that includes the titanium nitride film.

8. The method according to claim 7, wherein said titanium nitride film is formed by a mixture of gases titanium tetrachloride and ammonia.

9. The method according to claim 7, wherein said titanium nitride film is formed at 550° C. or more.

10. The method according to claim 1, wherein said lower electrode is made of a titanium nitride film.

11. The method according to claim 1, wherein said capacitance insulating film is formed from one from among an aluminum oxide film, a hafnium oxide film, a tantalum oxide film, and a zirconium oxide film, or wherein said capacitance insulating film is a laminated film that includes at least one from among the aluminum oxide film, the hafnium oxide film, the tantalum oxide film, and the zirconium oxide film.

12. The method according to claim 1, wherein said upper electrode is made of a titanium nitride film.

13. The method according to claim 1, wherein a formation temperature of said connection plug is higher than a film formation temperature of said capacitance insulating film.

14. The method according to claim 1, wherein a formation temperature of said connection plug is higher than a crystallization temperature of said capacitance insulating film.

15. The method according to claim 1, wherein a thermal load, when said connection plug is formed, makes leakage currents in said capacitor ten times larger or more.

16. The method according to claim 1, wherein a formation temperature of said connection plug is higher than a film formation temperature of said upper electrode.

17. The method according to claim 1, wherein a second interlayer insulating film is formed on said first interlayer insulating film after said connection plug is formed, and then the lower electrode is formed in said first interlayer insulating film and said second interlayer insulating film.

18. The method according to claim 17, wherein a polysilicon film is used to form said lower electrode.

19. The method according to claim 17, wherein said connection plug includes a tungsten film.

20. A method of manufacturing a semiconductor memory having a memory cell region including a plurality of capacitors holding information and transistors respectively provided for said capacitors and a peripheral circuit region provided with a circuit electrically connected to the memory cell region, comprising steps of:
forming an insulating film, into which a conductive plug connected to a source or a drain in said transistor and into which a first conductive layer which will become a part of said circuit are buried, on a semiconductor substrate;
forming an interlayer insulating film on said insulating film;
forming a first hole that exposes said first conductive layer, and a second hole that exposes said conductive plug expose in said interlayer insulating film;
burying a conductive film in said first hole to form a connection plug for connecting said first conductive layer and a second conductive layer arranged in a layer upper than said interlayer insulating film;
burying the conductive film into said second hole to form a lower electrode of said capacitor;
removing said interlayer insulating film in the memory cell region after said connection plug and said lower electrode are formed;
forming a capacitance insulating film in contact with said lower electrode; and
forming an upper electrode of the capacitor in contact with said capacitance insulating film.

21. The method according to claim 20, wherein said connection plug and said lower electrode are formed in the same step.

22. The method according to claim 20, wherein said connection plug and said lower electrode include at least a titanium nitride film.
